(19) United States
(12) Patent Application Publication
(10) Pub. No.: US 2025/0171899 A1
(43) Pub. Date: May 29, 2025

(54) METHOD OF FORMING OXIDE MATERIALS

(71) Applicant: ASM IP Holding B.V., Almere (NL)

(72) Inventors: Matthew Surman, Helsinki (FI); Emre Yarali, Helsinki (FI)

(21) Appl. No.: 18/963,342

(22) Filed: Nov. 27, 2024

Related U.S. Application Data
(60) Provisional application No. 63/603,992, filed on Nov. 29, 2023.

(51) Int. Cl. C23C 16/455; C01F 11/02; C01G 33/00; C23C 16/40; H01L 21/02

(52) U.S. Cl. CPC C23C 16/45553; C01F 11/02; C01G 33/00; C23C 16/404; H01L 21/02192; H01L 21/0228

(57) ABSTRACT

Described herein are methods and systems for forming oxides comprising an alkaline earth metal and optionally a transition metal. Suitable alkaline earth metals include strontium. Suitable transition metals include niobium.

### CROSS-REFERENCE TO RELATED APPLICATION(S)

This application claims the benefit of U.S. Provisional Application 63/603,992 filed on Nov. 29, 2023, the entire contents of which are incorporated herein by reference.

### FIELD OF INVENTION

The present disclosure is in the field of forming oxide materials that can be useful in integrated circuit manufacture. The oxide materials can comprise one or more of an alkaline earth metal and a transition metal.

### BACKGROUND OF THE DISCLOSURE

Dielectrics with a high dielectric constant are sought after in integrated circuit manufacture e.g. for application in MOSFET gate dielectrics and dielectrics in capacitors. In order for integrated circuit technology to advance to higher operating speeds, there is a need for dielectrics with an ever higher dielectric constant that nevertheless have a low defectivity. Low defectivity is desirable because it desirably lowers parasitic currents of the devices in which the dielectrics are incorporated. Thus, there is a need for dielectrics having a high dielectric constant and low defectivity.

### SUMMARY OF THE DISCLOSURE

Embodiments of the present disclosure can address one or more of the above-identified needs.

Described herein is a method of forming a layer comprising an alkaline earth metal and oxygen, the method comprising providing a substrate to a reaction chamber; executing a plurality of alkaline earth metal oxide deposition cycles, ones from the plurality of alkaline earth metal oxide deposition cycles comprising one or more alkaline earth metal carbonate deposition cycles to form an alkaline earth metal carbonate, and an oxidant pulse that comprises exposing the substrate to an oxidant to convert the alkaline earth metal carbonate film to an alkaline earth metal oxide; wherein ones from the one or more alkaline earth metal carbonate deposition cycles comprise an alkaline earth metal precursor pulse that comprises exposing the substrate to an alkaline earth metal precursor, the alkaline earth metal precursor comprising an alkaline earth metal, and, a first reactant pulse that comprises exposing the substrate to a first reactant.

Further described herein is a method of forming a layer on a substrate, the layer comprising an alkaline earth metal, a transition metal, and oxygen, the method comprising providing the substrate to a reaction chamber; executing a plurality of alkaline earth metal oxide deposition cycles, ones from the plurality of alkaline earth metal oxide deposition cycles comprising one or more alkaline earth metal carbonate deposition cycles to form an alkaline earth metal carbonate, an oxidant pulse that comprises exposing the substrate to an oxidant to convert the alkaline earth metal carbonate film to an alkaline earth metal oxide, and, one or more transition metal oxide deposition cycles to form a transition metal oxide; wherein ones from the one or more alkaline earth metal carbonate deposition cycles comprise an alkaline earth metal precursor pulse that comprises exposing the substrate to an alkaline earth metal precursor, the alkaline earth metal precursor comprising an alkaline earth metal, and, a first reactant pulse that comprises exposing the substrate to a first reactant; wherein ones from the one or more transition metal oxide deposition cycles comprise a transition metal precursor pulse that comprises exposing the substrate to a transition metal precursor, the transition metal precursor comprising a transition metal; and, a second reactant pulse that comprises exposing the substrate to a second reactant.

In some embodiments, the alkaline earth metal comprises strontium.

In some embodiments, the alkaline earth metal precursor comprises a compound having the general formula M(RnCp)₂, wherein M is an alkaline earth metal, R is a C1 to C6 alkyl, and n is an integer from at least 0 to at most 3.

In some embodiments, the transition metal precursor comprises niobium.

In some embodiments, the transition metal precursor comprises one or more alkylamido ligands.

In some embodiments, the transition metal precursor comprises one or more alkylimido ligands.

In some embodiments, the transition metal precursor comprises a heteroleptic precursor, the heteroleptic precursor comprising one or more alkylamido ligands and one or more alkylimido ligands.

In some embodiments, the transition metal precursor comprises Tris(diethylamido)(tert-butylimido)niobium.

In some embodiments, the oxidant comprises an oxygen reactant selected from H₂O, H₂O₂, O₂, O₃, oxygen ions, and oxygen radicals.

In some embodiments, the oxidant comprises ozone.

In some embodiments, at least one of the first reactant and the second reactant comprises a chalcogen.

In some embodiments, at least one of the first reactant and the second reactant comprises ozone.

In some embodiments, the first reactant pulse has a first duration, wherein the oxidant pulse has an oxidant pulse duration, and wherein the oxidant pulse duration is longer than the first duration.

In some embodiments, the oxidant comprises O₃, the first reactant comprises O₃, and the second reactant comprises H₂O or O₃.

Further described herein is a system comprising a reaction chamber and a controller, the system being constructed and arranged for carrying out a method as described herein.

In some embodiments, the system comprises an alkaline earth metal carbonate reaction chamber and a transition metal reaction chamber, the alkaline earth metal reaction chamber being constructed and arranged for forming an alkaline earth metal carbonate, and the transition metal reaction chamber being constructed and arranged for forming a transition metal oxide.

Further described herein is a film comprising an alkaline earth metal, a transition metal, and oxygen formed by means of a method as described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates an embodiment of a method 100 of forming a layer.

FIG. 2 illustrates an embodiment of a method for forming an alkaline earth metal carbonate.

FIG. 3 illustrates an embodiment of a method 300 of forming a layer comprising an alkaline earth metal, a transition metal, and oxygen.

FIG. 4 illustrates an embodiment of a method of forming a transition metal oxide.

FIG. 5 illustrates an embodiment of a system 500 as described herein.

FIG. 6 illustrates an embodiment of a pulse as described herein.

FIG. 7 illustrates an embodiment of a system 700 as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a cyclic deposition process as disclosed herein refers to an atomic layer deposition process.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

Note that, as used herein, ALD processes are not necessarily comprised of a sequence of self-limiting surface reactions.

Throughout the present disclosure, the following abbreviations are used: Cp stands for cyclopentadienyl, iPr stands for isopropyl.

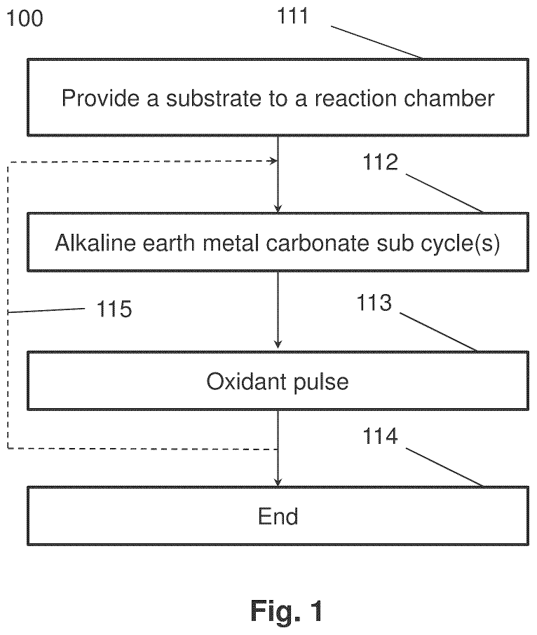

Referring to FIG. 1, described herein is an embodiment of a method 100 of forming a layer. The layer can comprise an alkaline earth metal. In some embodiments layer can further comprise oxygen. For example, the layer can comprise an alkaline earth metal oxide. In some embodiments, the layer substantially consists of an alkaline earth metal oxide. The method according to the embodiments of FIG. 1 comprises a step 111 of providing a substrate to a reaction chamber. The method further comprises executing a plurality of alkaline earth metal oxide deposition cycles 115. Ones from the plurality of alkaline earth metal oxide deposition cycles 115 comprise one or more alkaline earth metal carbonate deposition cycles 112 to form an alkaline earth metal carbonate. An alkaline earth metal carbonate can be formed, for example, by employing a metalorganic or organometallic alkaline earth metal precursor and at least partially combusting that precursor's ligands using an oxygen reactant such as ozone. Ones from the plurality of alkaline earth metal oxide deposition cycles 115 further comprise an oxidant pulse 113 that comprises exposing the substrate to an oxidant to convert the alkaline earth metal carbonate film to an alkaline earth metal oxide. After a suitable amount of alkaline earth metal oxide deposition cycles 115 has been executed, the method according to the embodiment of FIG. 1 ends 114. Thus, a layer comprising an alkaline earth metal can be formed. The layer can have a thickness of, for example, at least 0.3 nm to at most 1 mm, or from at least 1 nm to at most 100 m, or from at least 10 nm to at most 10 m, or from at least 100 nm to at most 1 km.

The resulting alkaline earth metal oxide can have an excellent quality and can be comprised in a gate dielectric in a transistor, or in a dielectric of a capacitor such as a metal-insulator-metal capacitor. In some embodiments, the resulting alkaline earth metal oxide can have a high dielectric constant, and it can consequently be used as a high-k material.

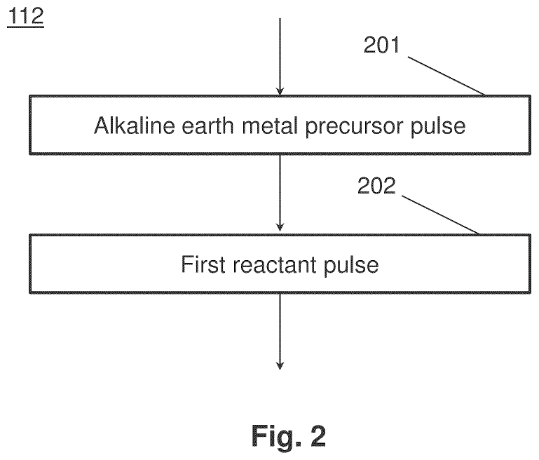

As described in the context of FIG. 1, forming the alkaline earth metal carbonate can comprise executing a cyclical deposition process comprising one or more alkaline earth metal carbonate deposition cycles 112. Suitably, and now referring to FIG. 2, an alkaline earth metal carbonate deposition cycle 112 can comprise an alkaline earth metal precursor pulse 201 and a first reactant pulse 202. The alkaline earth metal precursor pulse 201 comprises exposing the substrate to an alkaline earth metal precursor. The alkaline earth metal precursor comprises an alkaline earth metal. The first reactant pulse 202 comprises exposing the substrate to a first reactant. Optionally, subsequent pulses can be separated by a purge.

In some embodiments, forming the alkaline earth metal carbonate can comprise executing from at least 1 to at most 100 subsequent alkaline earth metal carbonate deposition cycles 112, or from at least 2 to at most 50 subsequent alkaline earth metal carbonate deposition cycles 112, or from at least 5 to at most 20 subsequent alkaline earth metal carbonate deposition cycles 112, or about 10 alkaline earth metal carbonate deposition cycles 112.

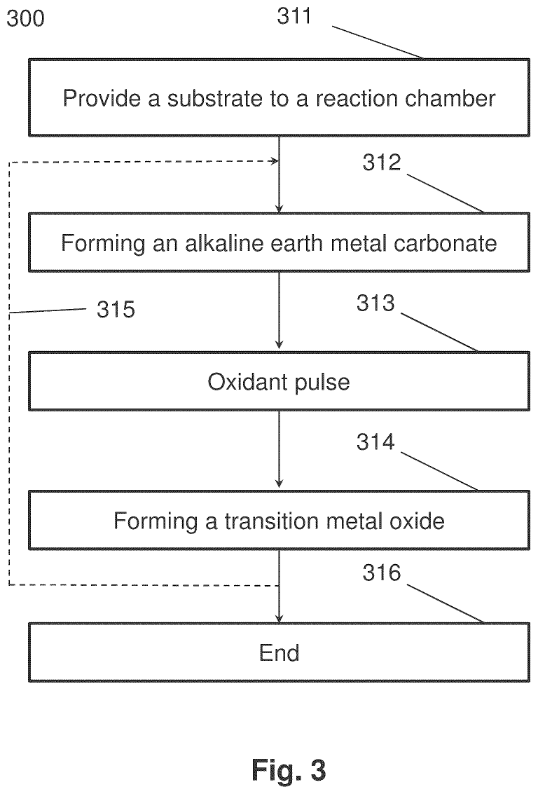

Referring now to FIG. 3, further described herein is an embodiment of a method 300 of forming a layer comprising an alkaline earth metal, a transition metal, and oxygen. The layer can be formed on a substrate. The method 300 according to the embodiment of FIG. 3 comprises a step of providing the substrate to a reaction chamber. The method further comprises executing a plurality of deposition cycles 315. Ones from the plurality of deposition cycles 315 comprise forming an alkaline earth metal carbonate 312. In some embodiments, forming the alkaline earth metal carbonate 312 can be done by executing one or more alkaline earth metal carbonate sub cycles. Ones from the plurality of deposition cycles 315 further comprise an oxidant pulse 313. In some embodiments, the oxidant pulse 313 directly follows forming the alkaline earth metal carbonate 312. The oxidant pulse 313 can suitably transform the alkaline earth metal carbonate into an alkaline earth metal oxide. Ones from the plurality of deposition cycles 315 further comprise forming a transition metal oxide 314. Forming the transition metal oxide 314 can be done by executing one or more transition metal oxide deposition cycles 314. Thus, in some embodiments, a laminate layer structure comprising alternating layers of alkaline earth metal oxide and transition metal oxide layers can be formed. Alternatively, the resulting layer can have a homogeneous composition. A homogeneous composition can be obtained, for example, by annealing a laminate layer structure and thus allowing diffusion to homogenize the resulting layer's composition. Additionally or alternatively, a homogeneous composition can be obtained by executing relatively low amounts of alkaline earth metal carbonate deposition cycles in succession and transition metal oxide deposition cycles in succession. Indeed, by forming stacks of alternating very thin layers, a layer structure can be obtained which is substantially homogeneous.

The resulting binary oxide comprising an alkaline earth metal and a transition metal can have an excellent quality and can be comprised in a gate dielectric in a transistor, or in a dielectric of a capacitor such as a metal-insulator-metal capacitor. In some embodiments, the resulting binary oxide can have a high dielectric constant, and it can consequently be used as a high-k material.

Advantageously, forming, e.g. periodically forming, a carbonate and then oxidizing the carbonate to form an oxide, allows forming the oxide at a high growth rate. For example, in a cyclical deposition process as described herein, e.g. an atomic layer deposition process, and using Sr(iPr₃Cp)₂ as an alkaline earth metal precursor it was found to be impossible to grow a SrO film with an acceptable growth-per-cycle using ozone as a reactant. Without the subject matter of the present disclosure being bound by any particular theory or mode of operation, it is believed that strontium oxide is not a good nucleation surface for continued growth using Sr(iPr₃Cp)₂.

Embodiments of the present disclosure circumvent this problem by first growing strontium carbonate, and then converting the strontium carbonate to strontium oxide, to result in growth of the oxide at a high growth rate.

Forming the alkaline earth metal carbonate can comprise executing a cyclical deposition process comprising one or more alkaline earth metal carbonate deposition cycles 112. Ones from the one or more alkaline earth metal carbonate deposition cycles can comprise an alkaline earth metal precursor pulse 201 and a first reactant pulse 202, as described in the context of FIG. 2.

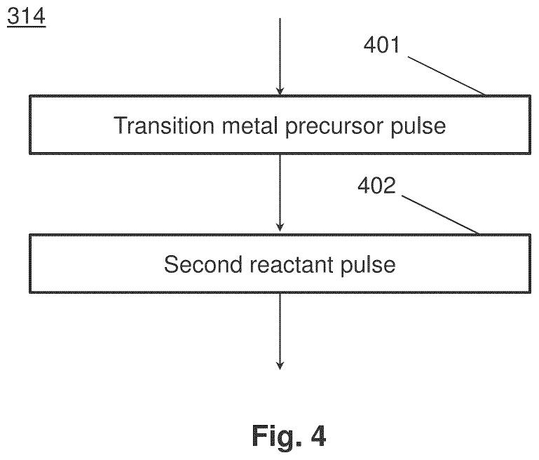

Forming the transition metal oxide can comprise executing a cyclical deposition process comprising one or more transition metal oxide deposition cycles 314, as illustrated by means of FIG. 4. Indeed, ones from the one or more transition metal oxide deposition cycles 314 can comprise executing a transition metal precursor pulse 401 and a second reactant pulse 402. The transition metal precursor pulse 401 can comprise exposing the substrate to a transition metal precursor. The transition metal precursor can comprise a transition metal. The second reactant pulse 402 can comprise exposing the substrate to a second reactant. Optionally, subsequent pulses can be separated by a purge.

In some embodiments, ones from the plurality of deposition cycles 315 can comprise an equal amount of alkaline earth metal deposition cycles and transition metal deposition cycles. In some embodiments ones from the plurality of deposition cycles 315 can comprise 0.01 to 100 alkaline earth metal carbonate deposition cycles for each transition metal deposition cycle. In some embodiments ones from the plurality of deposition cycles 315 can comprise 0.02 to 50 alkaline earth metal carbonate deposition cycles for each transition metal deposition cycle. In some embodiments ones from the plurality of deposition cycles 315 can comprise 0.05 to 20 alkaline earth metal carbonate deposition cycles for each transition metal deposition cycle. In some embodiments ones from the plurality of deposition cycles 315 can comprise 0.1 to 10 alkaline earth metal carbonate deposition cycles for each transition metal deposition cycle. In some embodiments ones from the plurality of deposition cycles 315 can comprise 0.5 to 2 alkaline earth metal carbonate deposition cycles for each transition metal deposition cycle.

In some embodiments, the first reactant and the second reactant are independently selected from an oxygen reactant such as H₂O, H₂O₂, O₂, O₃. In some embodiments, the oxygen reactant can comprise one or more plasma-generated species such as oxygen ions or radicals. In some embodiments, the first reactant and the second reactant are the same. In some embodiments, the first reactant and the second reactant are different. In some embodiments, the first reactant and the second reactant comprise ozone.

In some embodiments, the alkaline earth metal precursor comprises strontium and the transition metal precursor comprises niobium. Thus, an oxide, e.g. binary oxide, comprising strontium and niobium can be formed. In some embodiments, the material formed comprises Sr₂Nb₃O₁₀, which can desirably have a high dielectric constant and low defectivity.

In some embodiments, the alkaline earth metal is selected from beryllium, magnesium, calcium, strontium, and barium. In some embodiments, the alkaline earth metal comprises strontium.

In some embodiments, the alkaline earth metal precursor comprises a compound having the general formula M(RₙCp)₂, wherein M is an alkaline earth metal, R is a C1 to C6 alkyl, and n is an integer from at least 0 to at most 3. In some embodiments, M is strontium, R is isopropyl, and n is 3.

In some embodiments, R is selected from methyl, ethyl, propyl, butyl, and pentyl.

In some embodiments, n is 0, 1, 2, or 3.

In some embodiments, the alkaline earth metal precursor comprises a compound having the general formula

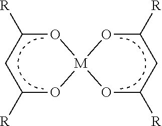

in which M is an alkaline earth metal and R is a C1 to C6 alkyl. In some embodiments, M is strontium and R is tert-butyl.

In some embodiments, the transition metal precursor comprises an element selected from the list consisting of scandium, titanium, vanadium, chromium, manganese, iron, cobalt, nickel, copper, zinc, yttrium, zirconium, niobium, molybdenum, ruthenium, rhodium, palladium, silver, cadmium, lutetium, hafnium, tantalum, tungsten, rhenium, osmium, iridium, platinum, gold, and mercury. In some embodiments, the transition metal precursor comprises niobium.

In some embodiments, the transition metal precursor comprises one or more alkylamido ligands.

In some embodiments, the transition metal precursor comprises one or more alkylimido ligands.

In some embodiments, the transition metal precursor comprises a heteroleptic precursor.

The heteroleptic precursor can comprise one or more alkylamido ligands and one or more alkylimido ligands.

In some embodiments, the transition metal precursor comprises tris(diethylamido)(tert-butylimido)niobium.

In some embodiments, the transition metal precursor corresponds to the general formula

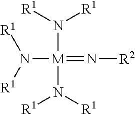

wherein M is a transition metal, and R¹ and R² are independently selected from a C1 to C6 alkyl. In some embodiments, M is niobium. In some embodiments, R¹ is ethyl. In some embodiments, R² is butyl. In some embodiments, R² is tert-butyl.

In some embodiments, R¹ is methyl. In some embodiments, R¹ is ethyl. In some embodiments, R¹ is propyl. In some embodiments, R¹ is butyl. In some embodiments, R¹ is pentyl. In some embodiments, R¹ is hexyl.

In some embodiments, R² is methyl. In some embodiments, R² is ethyl. In some embodiments, R² is propyl. In some embodiments, R² is butyl. In some embodiments, R² is pentyl. In some embodiments, R² is hexyl.

In some embodiments, the oxidant comprises an oxygen reactant. In some embodiments, the oxygen reactant is selected from H₂O, H₂O₂, O₂, and O₃. In some embodiments, the oxygen reactant comprises one or more plasma species such as oxygen ions and oxygen radicals.

In some embodiments, the oxidant comprises ozone.

In some embodiments, the first reactant and the second reactant are independently selected.

In some embodiments, the first reactant and the second reactant are identical. In some embodiments, the first reactant and the second reactant are different.

In some embodiments, at least one of the first reactant and the second reactant comprises a chalcogen.

In some embodiments, at least one of the first reactant and the second reactant comprises ozone.

In some embodiments, the first reactant comprises O₃ and the second reactant comprises H₂O.

In some embodiments, the oxidant comprises O₃, the first reactant comprises O₃, and the second reactant comprises H₂O.

In some embodiments, the oxidant comprises O₃, the first reactant comprises O₃, and the second reactant comprises H₂O or O₃.

In some embodiments, the oxidant pulse lasts longer than the first reactant pulse. Thus, in some embodiments, the first reactant pulse has a first duration, the oxidant pulse has an oxidant pulse duration, and the oxidant pulse duration is longer than the first duration. In some embodiments, both the oxidant and the first reactant comprise ozone.

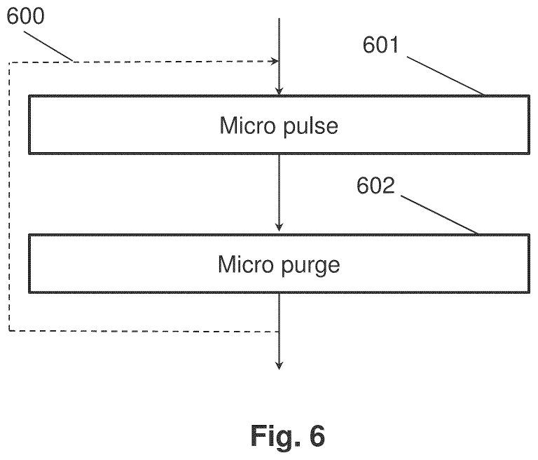

In some embodiments, at least one of the first reactant pulse, the second reactant pulse, and the oxidant pulse can comprise a plurality of micro pulses 601 and micro purges 602 as illustrated by FIG. 6, such as 2, 4, 6, 8, 10, or more micro pulses 601 and micro purges 602. In such embodiments, a pulse 600 can comprise a rapid succession of brief reactant or oxidant pulses and purges using a purge gas. For example, the micro pulse can be executed for 0.2 seconds, the micro purge can be executed for 0.5 seconds, and this pulse-purge cycle can be repeated 10 times.

In some embodiments, a method as described herein is carried out at a temperature of at least 100° C. to at most 400° C., or of at least 150° C. to at most 350° C., or of at least 200° C. to at most 300° C., or of about 250° C.

In some embodiments, a layer comprising an alkaline earth metal and a transition metal as formed using a method as described herein has an alkaline earth metal content of at least 5 atomic percent to at most 95 atomic percent and a transition metal content of at least 5 atomic percent to at most 95 atomic percent. In some embodiments, a layer comprising an alkaline earth metal and a transition metal as formed using a method as described herein has an alkaline earth metal content of at least 10 atomic percent to at most 90 atomic percent and a transition metal content of at least 10 atomic percent to at most 90 atomic percent. In some embodiments, a layer comprising an alkaline earth metal and a transition metal as formed using a method as described herein has an alkaline earth metal content of at least 20 atomic percent to at most 80 atomic percent and a transition metal content of at least 20 atomic percent to at most 80 atomic percent. In some embodiments, a layer comprising an alkaline earth metal and a transition metal as formed using a method as described herein has an alkaline earth metal content of at least 30 atomic percent to at most 70 atomic percent and a transition metal content of at least 30 atomic percent to at most 70 atomic percent. In some embodiments, a layer comprising an alkaline earth metal and a transition metal as formed using a method as described herein has an alkaline earth metal content of at least 40 atomic percent to at most 60 atomic percent and a transition metal content of at least 40 atomic percent to at most 60 atomic percent. These compositions can be determined using X-ray photoelectron spectroscopy (XPS), and are expressed on a total metal basis, e.g. with respect to the sum of the alkaline earth metal content and the transition metal content, without accounting for the oxygen atoms.

Further described herein is a system that comprises a reaction chamber and a controller. The system is constructed and arranged for carrying out a method as described herein.

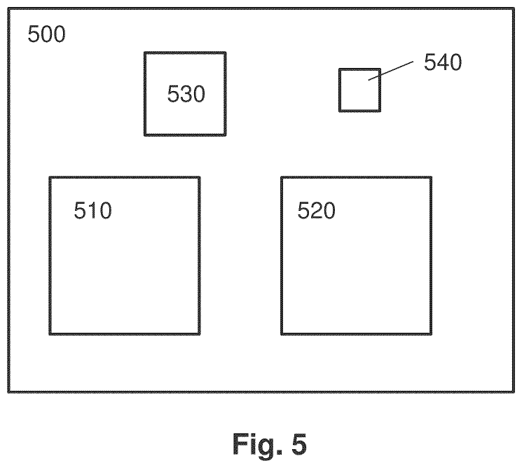

Referring to FIG. 5, a system 500 can comprise two reaction chambers 510,520, in particular an alkaline earth metal reaction chamber 510 and a transition metal reaction chamber 520. The alkaline earth metal reaction chamber 510 can be constructed and arranged for executing a plurality of alkaline earth metal deposition cycles. The transition metal reaction chamber 520 can be constructed and arranged for executing a plurality of transition metal deposition cycles. The system 500 further comprises a substrate transport robot 530 which is constructed and arranged for moving substrates to, from, and between the alkaline earth metal reaction chamber 510 and the transition metal reaction chamber 520. The system 500 can further comprise a controller 540 which is constructed and arranged for causing the system 500 to execute a method as described herein For example, in a method 300 according to the embodiment of FIG. 3, a substrate can be cycled between the alkaline earth metal reaction chamber 510 for forming the alkaline earth metal carbonate and the transition metal reaction chamber 520 for forming the transition metal oxide.

The oxidant pulse 313 can be carried out in the alkaline earth metal reaction chamber 520 after forming the alkaline earth metal carbonate, or in the transition metal reaction chamber 530 before forming the transition metal oxide 314. Cycling a substrate in this way can be particularly advantageous when the alkaline earth metal carbonate and the transition metal are formed at different temperatures, which can be useful, for example, to obtain a ternary film with a desirable stoichiometry such as Sr₂Nb₃O₁₀ which has a high dielectric constant. Of course, all steps of the method 300 according to the embodiment of FIG. 3 can also be carried out using only one reaction chamber, in some embodiments.

In some embodiments, the alkaline earth metal reaction chamber 510 and the transition metal reaction chamber 520 can be cyclical deposition, e.g. atomic layer deposition (ALD), reaction chambers. In such embodiments, certain number of cycles, e.g. 10 to 20 cycles, can be carried in each of the reaction chambers 510,520 before moving the substrate to the next. Thus, a nanolaminate structure can be formed comprising alternating layers of an alkaline earth metal oxide and a transition metal oxide. Such nanolaminates can have a large dielectric constant as such. Alternatively, such nanolaminates can be annealed to form a homogeneous or substantially homogeneous dielectric.

The reactants used in the two reaction chambers 510,520 can be the same or they can be different. In some embodiments, the first reactant comprises O₃ and the second reactant comprises H₂O, which can be done, for example, to form a nanolaminate as described herein, e.g. comprising alternating layers of strontium oxide and niobium oxide. In such embodiments, the transition metal reaction chamber 520 can be maintained at a higher temperature than the alkaline earth metal reaction chamber.

By executing a laminate's constituent deposition processes in different reaction chambers, these processes can be executed under optimal reaction processes which can advantageously enhance growth rate, enhance conformality, and reduce carbon content.

In an exemplary embodiment, the alkaline earth metal reaction chamber 510 can be employed for forming and oxidizing a strontium carbonate layer to form strontium oxide lamellae using atomic layer deposition. The alkaline earth metal reaction chamber 510 can be maintained at a temperature of 300° C. or higher and can be utilized to execute 10 to 15 consecutive cycles prior to oxidation. Bis(2,2,6,6-tetramethyl-3,5-heptanedionato)strontium or (iPr₃Cp)₂Sr can be employed as precursor. Water can be used as a reactant.

In an exemplary embodiment, the transition metal reaction chamber 520 can be employed for forming transition metal oxide lamellae using atomic layer deposition. The transition metal reaction chamber 520 can be maintained at a temperature of at least 200° C. to at most 275° C. Tris(diethylamido)(tert-butylimido)niobium can be used as a precursor and ozone or water can be used as a reactant.

In an exemplary embodiment, ozone was used as an oxidant. It was advantageously found that employing ozone as an oxidant in a method according to the embodiment of FIG. 3, the carbon concentration was reduced in strontium niobium oxide films.

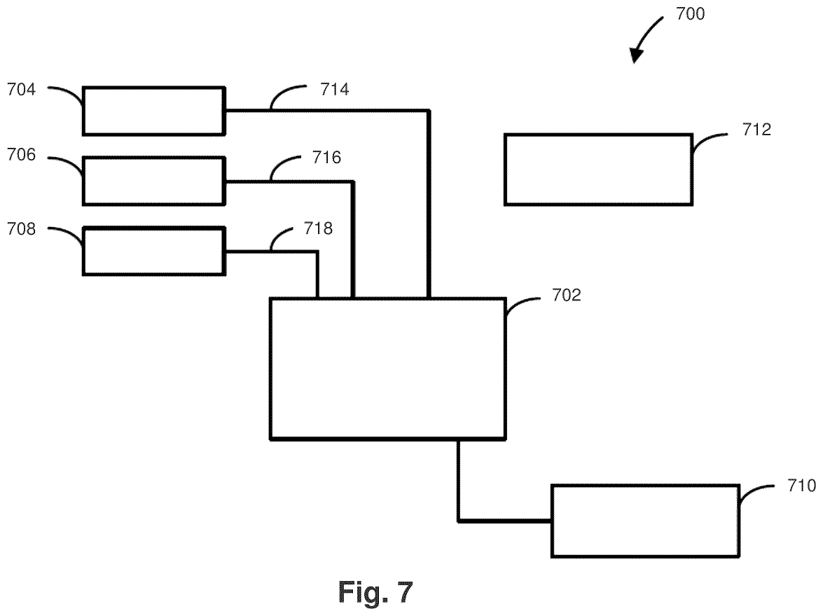

Referring to FIG. 7, further described herein is a system 700 that is constructed and arranged for carrying out an embodiment of a method as described herein.

In the illustrated example, the system 700 includes one or more reaction chambers 702, a precursor gas source 704, a reactant gas source 706, a purge gas source 708, an exhaust source 710, and a controller 712. Of course, other gas sources can be present, in some embodiments. For example, a system 700 can comprise all of an alkaline earth metal precursor source, a transition metal precursor source, a first reactant source, a second reactant source, and an oxidant source. The reaction chamber 702 can include any suitable reaction chamber, such as an ALD or CVD reaction chamber. For simplicity, the system 700 is described referring only to a generic precursor gas source 704 and a generic reactant gas source 706.

The precursor gas source 704 can include a vessel and one or more precursors as described herein-alone or mixed with one or more carrier (e.g., inert) gases. The reactant gas source 706 can include a vessel and one or more reactants as described herein-alone or mixed with one or more carrier gases. The purge gas source 708 can include one or more purge gases as described herein. Although illustrated with three gas sources 704-708, the system 700 can include any suitable number of gas sources. The gas sources 704-708 can be coupled to reaction chamber 702 via lines 714-718, which can each include flow controllers, valves, heaters, and the like. The exhaust 710 can include one or more vacuum pumps.

The controller 712 includes electronic circuitry and software to selectively operate valves, manifolds, heaters, pumps and other components included in the system 700. Such circuitry and components operate to introduce precursors, reactants, and purge gases from the respective sources 704-708. The controller 712 can control timing of gas pulse sequences, temperature of the substrate and/or reaction chamber, pressure within the reaction chamber, and various other operations to provide proper operation of the system 700. The controller 712 can include control software to electrically or pneumatically control valves to control flow of precursors, reactants and purge gases into and out of the reaction chamber 702. The controller 712 can include modules such as a software or hardware component, e.g., a FPGA or ASIC, which performs certain tasks. A module can advantageously be configured to reside on the addressable storage medium of the control system and be configured to execute one or more processes.

Other configurations of the system 700 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber 702. Further, as a schematic representation of a system, many components have been omitted for simplicity of illustration, and such components may include, for example, various valves, manifolds, purifiers, heaters, containers, vents, and/or bypasses.

During operation of the reactor system 700, substrates, such as semiconductor wafers (not illustrated), are transferred from, e.g., a substrate handling system to reaction chamber 702. Once substrate(s) are transferred to the reaction chamber 702, one or more gases from the gas sources 704-708, such as precursors, reactants, carrier gases, and/or purge gases, are introduced into reaction chamber 702.

Further described is a composition configured forming a layer comprising a transition metal and an alkaline earth metal on a substrate, the composition comprising one or more of an alkaline earth metal precursor and a transition metal precursor as described herein.

Further described is a vessel comprising at least one of an alkaline earth metal precursor and a transition metal precursor as described herein, wherein the vessel is configured to supply a vapor of the chemical precursor to a semiconductor processing apparatus chamber comprised in a system as described herein.

An alkaline earth metal and transition metal containing film deposition product, the product comprising: a alkaline earth metal precursor and a transition metal precursor as described a first vessel comprising the alkaline earth metal precursor; and a second vessel comprising the transition metal precursor, wherein the first and second vessels are configured to couple to a semiconductor apparatus, such as a system as described herein, via a reactant delivery system.

1. A method of forming a layer comprising an alkaline earth metal and oxygen, the method comprising
providing a substrate to a reaction chamber; and
executing a plurality of alkaline earth metal oxide deposition cycles, ones from the plurality of alkaline earth metal oxide deposition cycles comprising
one or more alkaline earth metal carbonate deposition cycles to form an alkaline earth metal carbonate, and
an oxidant pulse that comprises exposing the substrate to an oxidant to convert the alkaline earth metal carbonate film to an alkaline earth metal oxide,
wherein ones from the one or more alkaline earth metal carbonate deposition cycles comprise
an alkaline earth metal precursor pulse that comprises exposing the substrate to an alkaline earth metal precursor, the alkaline earth metal precursor comprising an alkaline earth metal, and
a first reactant pulse that comprises exposing the substrate to a first reactant.

2. A method of forming a layer on a substrate, the layer comprising an alkaline earth metal, a transition metal, and oxygen, the method comprising
providing the substrate to a reaction chamber; and
executing a plurality of alkaline earth metal oxide deposition cycles, ones from the plurality of alkaline earth metal oxide deposition cycles comprising
one or more alkaline earth metal carbonate deposition cycles to form an alkaline earth metal carbonate,
an oxidant pulse that comprises exposing the substrate to an oxidant to convert the alkaline earth metal carbonate film to an alkaline earth metal oxide, and
one or more transition metal oxide deposition cycles to form a transition metal oxide,
wherein ones from the one or more alkaline earth metal carbonate deposition cycles comprise
an alkaline earth metal precursor pulse that comprises exposing the substrate to an alkaline earth metal precursor, the alkaline earth metal precursor comprising an alkaline earth metal, and
a first reactant pulse that comprises exposing the substrate to a first reactant;
wherein ones from the one or more transition metal oxide deposition cycles comprise a transition metal precursor pulse that comprises exposing the substrate to a transition metal precursor, the transition metal precursor comprising a transition metal; and
a second reactant pulse that comprises exposing the substrate to a second reactant.

3. The method according to claim 1, wherein the alkaline earth metal comprises strontium.

4. The method according to claim 1, wherein the alkaline earth metal precursor comprises a compound having the general formula M(RₙCp)₂, wherein M is an alkaline earth metal, R is a C1 to C6 alkyl, and n is an integer from at least 0 to at most 3.

5. The method according to claim 2, wherein the transition metal precursor comprises niobium.

6. The method according to claim 2, wherein the transition metal precursor comprises one or more alkylamido ligands.

7. The method according to claim 2, wherein the transition metal precursor comprises one or more alkylimido ligands.

8. The method according to claim 2, wherein the transition metal precursor comprises a heteroleptic precursor, the heteroleptic precursor comprising one or more alkylamido ligands and one or more alkylimido ligands.

9. The method according to claim 2, wherein the transition metal precursor comprises Tris(diethylamido)(tert-butylimido)niobium.

10. The method according claim 1, wherein the oxidant comprises an oxygen reactant selected from H₂O, H₂O₂, O₂, O₃, oxygen ions, and oxygen radicals.

11. The method according to claim 1, wherein the oxidant comprises ozone.

12. The method according to claim 2, wherein at least one of the first reactant and the second reactant comprises a chalcogen.

13. The method according to claim 2, wherein at least one of the first reactant and the second reactant comprises ozone.

14. The method according to claim 1, wherein the first reactant pulse has a first duration, wherein the oxidant pulse has an oxidant pulse duration, and wherein the oxidant pulse duration is longer than the first duration.

15. The method according to claim 2, wherein the oxidant comprises O₃, the first reactant comprises O₃, and the second reactant comprises H₂O or O₃.

16. A system comprising a reaction chamber and a controller, the system being constructed and arranged for carrying out the method according to claim 1.

17. The system according to claim 16, comprising an alkaline earth metal carbonate reaction chamber and a transition metal reaction chamber, the alkaline earth metal carbonate reaction chamber being constructed and arranged for forming an alkaline earth metal carbonate, and the transition metal reaction chamber being constructed and arranged for forming a transition metal oxide.
